(19) United States
(12) Patent Application Publication
(10) Pub. No.: US 2025/0079383 A1
(43) Pub. Date: Mar. 6, 2025

(54) SEMICONDUCTOR DEVICE

(71) Applicant: Sanken Electric Co., Ltd., Saitama-ken (JP)

(72) Inventor: Takashi Haishima, Saitama-ken (JP)

(73) Assignee: Sanken Electric Co., Ltd., Saitama-ken (JP)

(21) Appl. No.: 18/800,122

(22) Filed: Aug. 11, 2024

(30) Foreign Application Priority Data
Aug. 29, 2023 (JP) 2023-138886

(51) Int. Cl. H01L 23/00; H01L 23/538; H01L 25/065

(52) U.S. Cl. CPC H01L 24/29; H01L 23/538; H01L 24/32; H01L 24/40; H01L 24/73; H01L 25/0655; H01L 2224/29082; H01L 2224/32245; H01L 2224/40245; H01L 2224/73263

(57) ABSTRACT

A semiconductor device includes a semiconductor element on a substrate having a conductive pattern. The semiconductor element includes electrodes provided on a first surface and an electrode provided on a second surface, each of the electrodes provided on the first surface is bonded to the conductive pattern of the substrate via a conductive spacer, and the electrode provided on the second surface is bonded to a pad surface of a conductive clip lead.

### CROSS-REFERENCE TO RELATED APPLICATION

This application claims the priority benefit of Japan application serial no. 2023-138886, filed on Aug. 29, 2023. The entirety of the above-mentioned patent application is hereby incorporated by reference herein and made a part of this specification.

### BACKGROUND

### Technical Field

The disclosure relates to a semiconductor device.

### Related Art

A general semiconductor device is manufactured by electrically connecting a semiconductor element to a circuit board formed with a metal pattern or to a lead frame including inner leads, and performing resin-sealing thereon. Specifically, as a typical semiconductor element, a power chip such as a transistor or a diode that handles a high power is mainly bonded to the metal pattern by soldering in a reflow process. Further, in the case where a power chip is present with a control chip such as a control IC that does not handle a high power as the power chip, it is common to dispose the power chip and the control chip at different positions on the circuit board or in different regions of the lead frame. Further, in some cases, the control chip may be connected by a conductive adhesive instead of soldering.

The power chip (hereinafter also referred to as a semiconductor element or simply a chip) is expected to handle an increasingly higher power as applications thereof expand. At the same time, techniques for improving integration and thinning are also advancing.

To improve integration, a technique of flip chip bonding (FCB) has been disclosed. The FCB involves mounting an electrode of a first surface of a power chip, which includes electrodes on both surfaces, to a first substrate, flipping by 180 degrees, and then bonding an electrode of a second surface of the power chip to a second substrate (see Patent Document 1: Japanese Patent Application Laid-Open No. 2014-107506). Compared to conventional wire bonding (WB), the FCB has been known to save space and exhibit reduced inductance components due to a reduced wiring length, which is suitable for high frequencies.

To achieve thinning, as an example of thinning of electrodes, a technique of Cu pillars (arrays of pillar-shaped Cu bumps (protrusions)) has been disclosed (see Patent Document 2: Japanese Patent Application Laid-Open No. 2012-151183).

In the case of using a semiconductor element such as a power chip that handles a high power and further improving integration and thinning, there are three issues to address.

First, a heat dissipation performance is to be ensured. To prevent the semiconductor element from thermal destruction due to a temperature rise resulting from power loss, sufficient heat dissipation is necessary.

Second, an impedance of a path is to be reduced. As the power handled by the semiconductor element increases, a current (I) flowing therethrough also increases. Thus, if an impedance (Z) of the path to which the semiconductor element is bonded is high, a power loss (I²×|Z|) in the path becomes large, leading to heat generation and a decrease in efficiency. To avoid this, the impedance of the path should be kept low.

Third, an insulation distance is to be ensured. With improvements in integration and thinning, a distance between electrodes (e.g., a first electrode and a second electrode of a semiconductor element) of the semiconductor element becomes small. Thus, an electrode (e.g., conductive pattern of the substrate) on the component to be bonded with the first electrode becomes close not only to the first electrode but also to the second electrode. In such cases, due to an even slight misalignment during bonding, the insulation distance between the second electrode and the conductive pattern on the substrate bonded with the first electrode of the semiconductor element cannot be ensured, potentially causing a short or damage to the semiconductor element. To avoid this, the insulation distance should be ensured.

### SUMMARY

A semiconductor device of an embodiment of the disclosure includes a semiconductor element on a substrate having a conductive pattern. The semiconductor element includes a plurality of electrodes provided on a first surface and an electrode provided on a second surface, each of the plurality of electrodes provided on the first surface is bonded to the conductive pattern of the substrate via a conductive spacer, and the electrode provided on the second surface is bonded to a pad surface of a conductive clip lead.

With such a semiconductor device, each of the plurality of electrodes of the semiconductor element provided on the first surface is bonded to the conductive pattern of the substrate via the conductive spacer, and heat can be dissipated. In addition, the electrode of the semiconductor element provided on the second surface is bonded to the pad surface of the conductive clip lead, and heat can be dissipated. Thus, since heat can be dissipated via each of the electrodes on both surfaces of the semiconductor element, a sufficient heat dissipation performance can be ensured.

Further, each of the plurality of electrodes of the semiconductor element provided on the first surface is bonded to the conductive pattern of the substrate via the conductive spacer, and the electrode of the semiconductor element provided on the second surface is bonded to the pad surface of the conductive clip lead. Since an impedance of a path after bonding is determined by a shape of the conductive pattern of the substrate or a shape of the pad surface of the clip lead, the impedance may be adjusted in any manner based on these shapes. Specifically, since both are planar, by increasing areas thereof, more current can be flowed easily. In other words, by increasing the areas, the impedance of the path can be reduced.

Further, since each of the plurality of electrodes of the semiconductor element provided on the first surface is bonded to the conductive pattern of the substrate via the conductive spacer, a distance from each of the plurality of electrodes to the conductive pattern of the substrate can be increased by a thickness of the spacer, and insulation distances can be easily ensured. Furthermore, with the spacer provided, a gap surrounded by the plurality of electrodes, the spacer, and the conductive pattern is widened, so it also becomes possible to fill the gap with an insulating resin material, and with the insulating resin material filled, the insulation performance can be further enhanced.

Further, the clip lead may further include a terminal surface, and the terminal surface may be bonded to the conductive pattern of the substrate.

With such a planar terminal surface, not only can the terminal surface itself dissipate heat, but by further bonding to the conductive pattern by surface contact, heat can be efficiently transferred and dissipated from the terminal surface to the conductive pattern. Furthermore, since the configuration can remain a planar shape from the pad surface via the terminal surface to the conductive pattern, the area is not narrowed midway, and the low impedance of the path can be maintained.

Further, a wire for wiring may be bonded to a surface of the clip lead opposite to the pad surface.

With such a configuration, heat can be dissipated by the pad surface of the clip lead, and even if a connection destination is located at a position (e.g., a distant position) difficult to connect with the clip lead, the wire can be extended to be wired flexibly.

Further, the semiconductor device may further include an insulating resist provided around the spacer on the conductive pattern of the substrate, and the semiconductor element and the conductive pattern may be bonded to each other by a solder.

With such a configuration, the solder melted on the conductive pattern is dammed by the insulating resist and does not spread further outward. In addition to bonding opposing surfaces of the conductive pattern and the spacer, the solder climbs up in a gap between an inner side of the insulating resist and a periphery of the spacer, and can adhere to a lateral surface of the spacer to provide bonding by wrapping from a lower surface to the lateral surface of the spacer. Accordingly, the semiconductor element and the conductive pattern can be reliably bonded to each other.

Further, the spacer may be a Cu pillar.

With such Cu pillars, the conductive spacer which connects the plurality of electrodes and the conductive pattern can be reliably realized.

As described above, according to the semiconductor device of the disclosure, each of the plurality of electrodes of the semiconductor element provided on the first surface is bonded to the conductive pattern of the substrate via the conductive spacer, and heat can be dissipated. In addition, the electrode of the semiconductor element provided on the second surface is bonded to the pad surface of the conductive clip lead, and heat can be dissipated. Thus, since heat can be dissipated via the electrodes on both surfaces of the semiconductor element, a sufficient heat dissipation performance can be ensured.

Further, each of the plurality of electrodes of the semiconductor element provided on the first surface is bonded to the conductive pattern of the substrate via the conductive spacer, and the electrode of the semiconductor element provided on the second surface is bonded to the pad surface of the conductive clip lead. Since an impedance of a path after bonding is determined by a shape of the conductive pattern of the substrate or a shape of the pad surface of the clip lead, the impedance may be adjusted in any manner based on these shapes. Specifically, since both are planar, by increasing widths of the surfaces, more current can be flowed easily. In other words, by increasing the widths of the surfaces, the impedance of the path can be reduced.

Further, since each of the plurality of electrodes of the semiconductor element provided on the first surface is bonded to the conductive pattern of the substrate via the conductive spacer, a distance from each of the plurality of electrodes to the conductive pattern of the substrate can be increased by a thickness of the spacer, and insulation distances can be easily ensured. Furthermore, with the spacer provided, a gap surrounded by the plurality of electrodes, the spacer, and the conductive pattern is widened, so it also becomes possible to fill the gap with an insulating resin material, and with the insulating resin material filled, the insulation performance can be further enhanced.

### BRIEF DESCRIPTION OF DRAWINGS

FIG. 1 is a schematic lateral cross-sectional view of a semiconductor device according to a first embodiment of the disclosure.

FIG. 2A to FIG. 2D are schematic plan views of the semiconductor device according to the first embodiment of the disclosure.

FIG. 3 is a schematic longitudinal cross-sectional view of a semiconductor device according to a second embodiment of the disclosure.

FIG. 4 is a schematic plan view of a semiconductor device according to another embodiment of the disclosure.

FIG. 5 is a schematic longitudinal cross-sectional view of a semiconductor device according to another embodiment of the disclosure.

FIG. 6 is a schematic plan view of a semiconductor device according to a third embodiment of the disclosure.

FIG. 7 is a schematic lateral cross-sectional view of the semiconductor device according to the third embodiment of the disclosure.

FIG. 8 is a schematic longitudinal cross-sectional view of the semiconductor device according to the third embodiment of the disclosure.

FIG. 9A and FIG. 9B are schematic plan views of a semiconductor device according to a fourth embodiment of the disclosure.

FIG. 10 is a schematic lateral cross-sectional view of the semiconductor device according to the fourth embodiment of the disclosure.

FIG. 11A, FIG. 11B, and FIG. 11C are schematic views of a semiconductor device and a semiconductor element according to a fifth embodiment of the disclosure.

FIG. 12A, FIG. 12B, and FIG. 12C are schematic views of a Cu pillar according to the fifth embodiment of the disclosure.

### DESCRIPTION OF EMBODIMENTS

Embodiments of the disclosure provide a semiconductor device capable of ensuring a heat dissipation performance, reducing an impedance of path, and ensuring an insulation distance.

The disclosure will be described in detail below but is not limited to the description.

As described above, to use a semiconductor element that handles a high power and further improve integration and thinning, there has been a demand for a semiconductor device that can ensure a heat dissipation performance, reduce an impedance of a path, and ensure an insulation distance.

As a result of intensive studies, the inventor has found that the above issue can be solved by devising a bonding structure of electrodes of the semiconductor element, and has thus completed the disclosure.

That is, the disclosure is a semiconductor device including a semiconductor element on a substrate having a conductive pattern. The semiconductor element includes a plurality of electrodes provided on a first surface and an electrode provided on a second surface. Each of the plurality of electrodes provided on the first surface is bonded to the conductive pattern of the substrate via a conductive spacer, and the electrode provided on the second surface is bonded to a pad surface of a conductive clip lead.

Details will be described with reference to the drawings.

Herein, the substrate is not particularly limited as long as a conductive pattern is formed on a surface thereof. The substrate may also be a substrate having a metal pattern also formed on a back surface thereof, or may also be a multilayer substrate. For example, a direct bonding copper (DBC) substrate may be adopted.

The conductive pattern is not particularly limited as long as a solder can be bonded, and the conductive pattern may be a copper pattern.

The solder is not particularly limited as long as it can fix the semiconductor element. For example, a lead-free solder may be adopted.

The solder is not particularly limited but may be printed in advance, and bonded by heating and melting in a reflow process.

The semiconductor element is not particularly limited but may be a power chip such as a diode or a transistor. Further, an IGBT or a power MOSFET may be adopted.

The electrode is not particularly limited as long as it is conductive and can be bonded by a solder, and the electrode may be made of Cu or Al.

The conductive spacer is not particularly limited as long as it is conductive and can be bonded by the solder. The conductive spacer may be made of Cu or may be Cu pillars.

Furthermore, the conductive spacer may also be plated, and in the case of plating, the plating may be made of Sn or the like.

The conductive clip lead is not particularly limited as long as it is conductive and can be bonded by the solder. The conductive clip lead may be a metal plate made of Cu, Al, SUS, Fe, or another alloy.

### First Embodiment

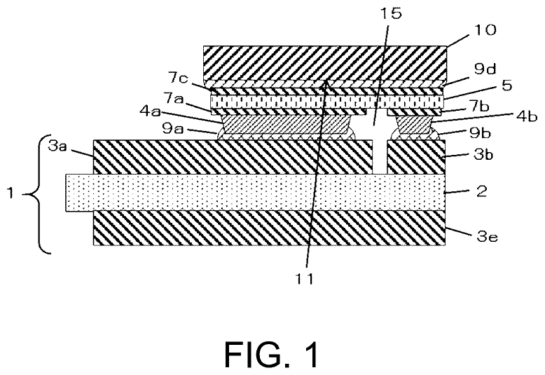

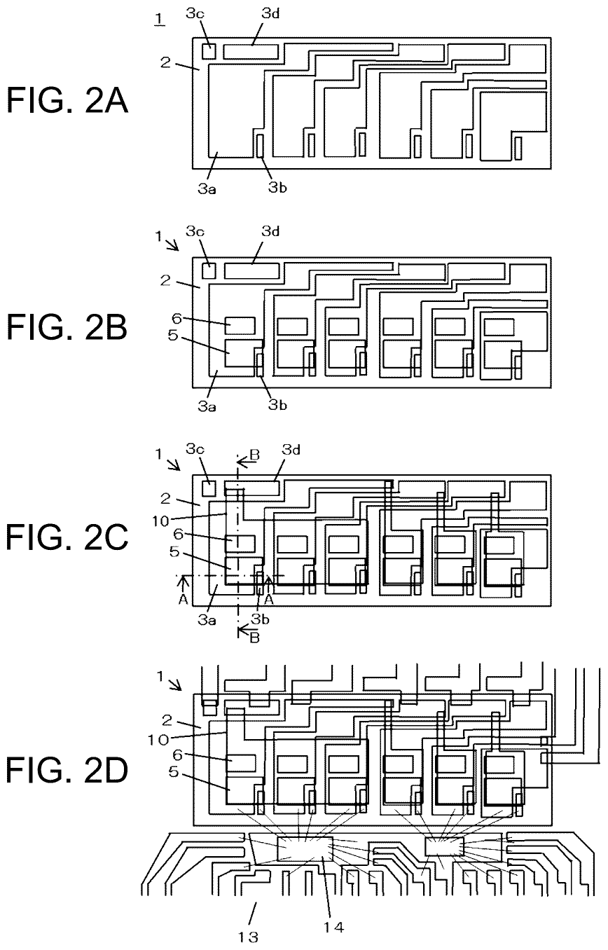

A first embodiment of the disclosure will be described with reference to FIG. 1 to FIG. 2D. FIG. 1 is a schematic lateral cross-sectional view of a semiconductor device, and FIG. 2A to FIG. 2D are schematic plan views. To clearly show the components, FIG. 2A to FIG. 2D illustrate steps for manufacturing the semiconductor device. Herein, FIG. 1 is a cross-sectional view taken along line A-A in FIG. 2C.

As shown in FIG. 1, the semiconductor device according to this embodiment is a semiconductor device including semiconductor elements 5 and 6 on a substrate 1 having a conductive pattern. In particular, the semiconductor element 5 includes a plurality of electrodes 7a and 7b provided on a first surface and an electrode 7c provided on a second surface. The plurality of electrodes 7a and 7b provided on the first surface are respectively bonded to conductive patterns 3a and 3b of the substrate 1 via conductive spacers 4a and 4b, and the electrode 7c provided on the second surface is bonded to a pad surface 11 of a conductive clip lead 10.

With such a semiconductor device, the plurality of electrodes 7a and 7b of the semiconductor element 5 provided on the first surface are respectively bonded to the conductive patterns 3a and 3b of the substrate 1 via the conductive spacers 4a and 4b, and heat can be dissipated through the entire substrate 1. In addition, the electrode 7c of the semiconductor element 5 provided on the second surface is bonded to the pad surface 11 of the conductive clip lead 10, and heat can be dissipated through the entire clip lead 10. Thus, since heat can be dissipated extensively via each of the electrodes 7a to 7c on both surfaces of the semiconductor element 5, a sufficient heat dissipation performance can be ensured.

Further, the plurality of electrodes 7a and 7b of the semiconductor element 5 provided on the first surface are respectively bonded to the conductive patterns 3a and 3b of the substrate 1 via the conductive spacers 4a and 4b, and the electrode 7c of the semiconductor element 5 provided on the second surface is bonded to the pad surface 11 of the conductive clip lead 10. Since an impedance of a path after bonding is determined by shapes of the conductive patterns 3a and 3b of the substrate 1 or a shape of the pad surface 11 of the clip lead 10, the impedance may be adjusted in any manner based on these shapes. Specifically, since both are planar, by increasing areas thereof, more current can be flowed easily. Particularly, as shown in FIG. 1 to FIG. 3, the conductive pattern 3a and the pad surface 11 of the clip lead 10 have larger areas than the semiconductor element 5. Thus, by increasing the areas, more current can be easily flowed, and the impedance of the path can be reduced.

Further, as shown in FIG. 1, since the plurality of electrodes 7a and 7b of the semiconductor element 5 provided on the first surface are respectively bonded to the conductive patterns 3a and 3b of the substrate via the conductive spacers 4a and 4b, distances from the plurality of electrodes 7a and 7b respectively to the conductive patterns 3a and 3b of the substrate can be increased by thicknesses of the spacers 4a and 4b, and insulation distances (in this case, particularly an insulation distance between the electrode 7a and the conductive pattern 3b not to be bonded together, and an insulation distance between the electrode 7b and the conductive pattern 3a not to be bonded together) can be easily ensured. For example, in the case of mounting the semiconductor element 5 to the substrate 1, even if the semiconductor element 5 is slightly displaced in a left-right direction in FIG. 1 with respect to the substrate 1, the insulation distance can still be ensured since a distance is present in an up-down direction (thickness direction of the spacers 4a and 4b). Furthermore, with the spacers 4a and 4b provided, a gap 15 surrounded by the plurality of electrodes 7a and 7b, the spacers 4a and 4b, and the conductive patterns 3a and 3b is widened. Even if the electrodes 7a and 7b are close together due to improvements in integration and thinning, with the gap 15 widened, it also becomes possible to fill the gap 15 with an insulating resin material, and with the insulating resin material filled, the insulation performance can be further enhanced.

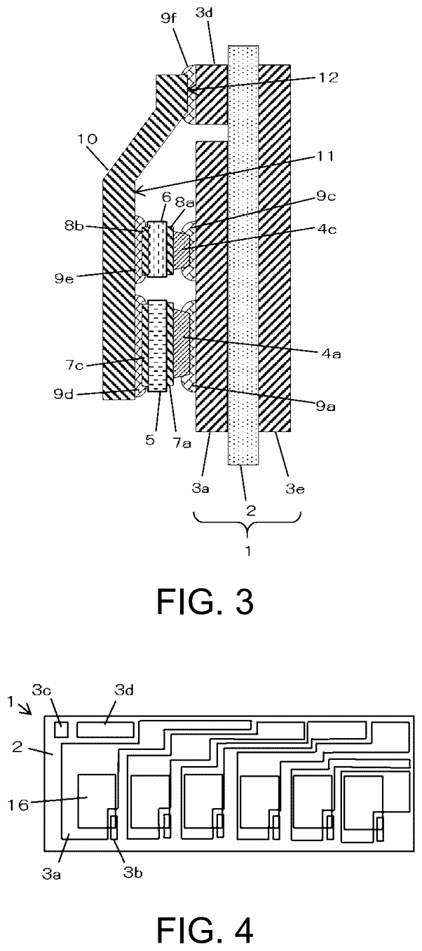

Next, with reference to FIG. 2A to FIG. 2D, steps for manufacturing the semiconductor device will be described. First, FIG. 2A is a view of a step of preparing a substrate, showing that a substrate 1 includes conductive patterns 3a to 3d on an upper surface of a ceramic base material 2. Although many conductive patterns are also present on the right side of the conductive patterns 3a to 3d, reference signs thereof are omitted herein for clarity. Further, a conductive pattern 3e is also provided on a lower surface of the substrate 1 (see FIG. 1 and FIG. 3).

Next, FIG. 2B is a view of a step of mounting power chips (semiconductor elements) 5 and 6 on the substrate 1 via conductive spacers 4a to 4c (see FIG. 1 and FIG. 3). Although five sets of power chips are also present on the right side of the power chips 5 and 6, reference signs thereof are omitted herein. Further, although with elements and the like disposed on patterns, the underlying patterns and the like would become invisible, herein, all configurations are illustrated to be visible for clarity of positional relationships (which also applies to FIG. 2C and FIG. 2D). Herein, the power chip 5 is an IGBT, and includes two electrodes 7a and 7b on a first surface (surface opposed to the substrate 1). The wider electrode is a source electrode 7a, and the narrower electrode is a gate electrode 7b. The electrodes 7a and 7b are respectively bonded to conductive patterns 3a and 3b via spacers 4a and 4b. The power chip 6 is a diode, includes one electrode 8a on a first surface (surface opposed to the substrate 1), and is bonded to the conductive pattern 3a via a spacer 4c. Herein, solders 9a to 9c are used for bonding.

Next, FIG. 2C is a view of a step of mounting a conductive clip lead 10. As shown in FIG. 3, a pad surface 11 of the clip lead 10 and electrodes 7c and 8b provided on second surfaces of the power chips 5 and 6 are bonded to each other by solders 9d and 9e. Further, the clip lead 10 further includes a terminal surface 12, which is bonded with a conductive pattern 3d of the substrate by a solder 9f.

Next, FIG. 2D is a view of a step of integrating the substrate 1 with a lead frame 13 to complete the semiconductor device. A control chip 14 is mounted to the lead frame 13. Since the control chip 14 does not handle a power as high, wire bonding (WB) is performed between the control chip 14 and the substrate 1.

### Second Embodiment

FIG. 3 is a schematic longitudinal cross-sectional view taken along line B-B in FIG. 2C. As shown in FIG. 3, the clip lead 10 further includes a terminal surface 12, which is bonded with a conductive pattern 3d of the substrate by a solder 9f. Other portions are similar to those in the above embodiment.

With such a clip lead 10 including a planar terminal surface 12, not only can the terminal surface 12 itself dissipate heat, but by further bonding to the conductive pattern 3d by surface contact, heat can be efficiently transferred and dissipated from the terminal surface 12 to the conductive pattern 3d. Furthermore, since the configuration can remain a wide planar shape from the pad surface 11 via the terminal surface 12 to the conductive pattern 3d, the area is not narrowed due to, for example, passing through a wire with a narrow cross-sectional area midway, and the low impedance of the path can be maintained.

In this embodiment, the semiconductor elements 5 and 6 are assumed to be general silicon types composed of two chips including an IGBT and a diode, but the disclosure is not limited thereto.

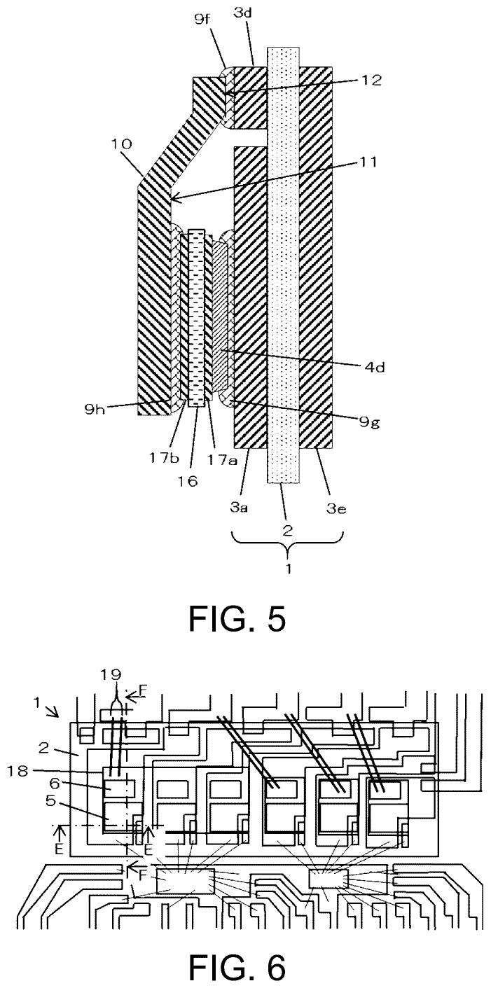

In another embodiment, for example, as one chip only, a SiC-type IGBT may be configured. The example of one chip will be described with reference to FIG. 4 and FIG. 5. FIG. 4 is a plan view, and FIG. 5 is a longitudinal cross-sectional view.

A semiconductor element 16 is one chip and is a SiC-type IGBT. Compared to two chips (semiconductor elements 5 and 6 in FIG. 2B), FIG. 4 shows one chip in a shape extending in the up-down direction on the paper. Further, in the longitudinal cross-section, compared to the two chips in FIG. 3, in the one chip in FIG. 5, shapes of an electrode 17a on a first surface (surface opposed to the substrate 1), an electrode 17b on a second surface of the semiconductor element 16, a spacer 4d, and solders 9g and 9h are different. Herein, the lateral cross-sectional view does not differ from FIG. 1 and is thus omitted. However, even with one chip, since two electrodes are similarly provided on the first surface (surface opposed to the substrate 1) to bond to the conductive patterns 3a and 3b, issues are similar to the case of two chips, and the issues can be solved by similar means.

### Third Embodiment

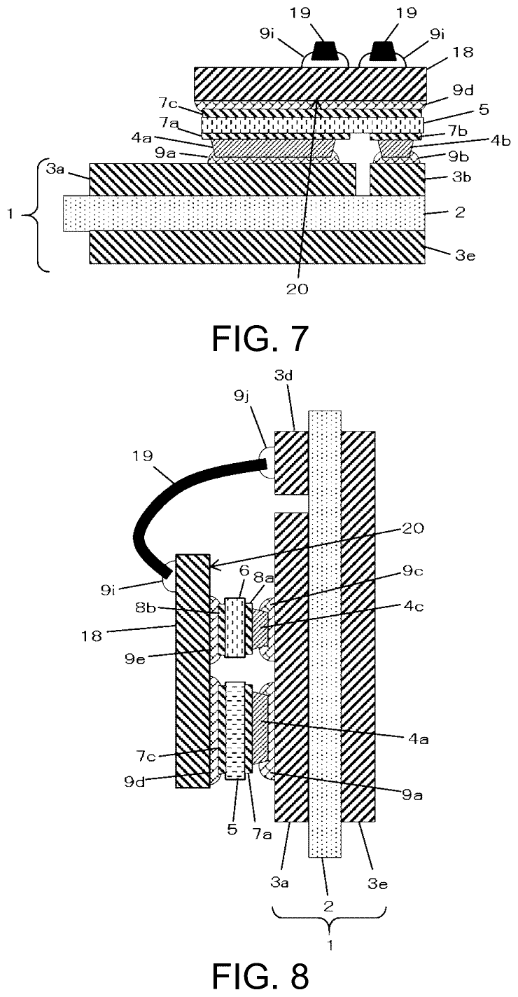

A third embodiment of the disclosure will be described with reference to FIG. 6 to FIG. 8. FIG. 6 is a schematic plan view. FIG. 7 is a schematic lateral cross-sectional view taken along line E-E in FIG. 6. FIG. 8 is a schematic longitudinal cross-sectional view taken along line F-F in FIG. 6.

The third embodiment differs from the second embodiment in that a clip lead 18 has a flat shape when viewed from a lateral side, a terminal surface is not provided, and a wire 19 is included.

Specifically, one end of the wire 19 for wiring is bonded by a solder 9i to a surface of the clip lead 18 opposite to the pad surface 20, and the other end of the wire 19 is bonded by a solder 9j to the conductive pattern 3d. Further, the wire 19 may also be a thick wire of aluminum or the like that is ultrasonically wire-bonded without using the solders 9i and 9j.

With such a configuration, heat can be dissipated by the pad surface 20 of the clip lead 18, and even if a connection destination is located at a position (e.g., a distant position) difficult to connect with the clip lead, the other end of the wire 19 can be extended to be wired flexibly.

### Fourth Embodiment

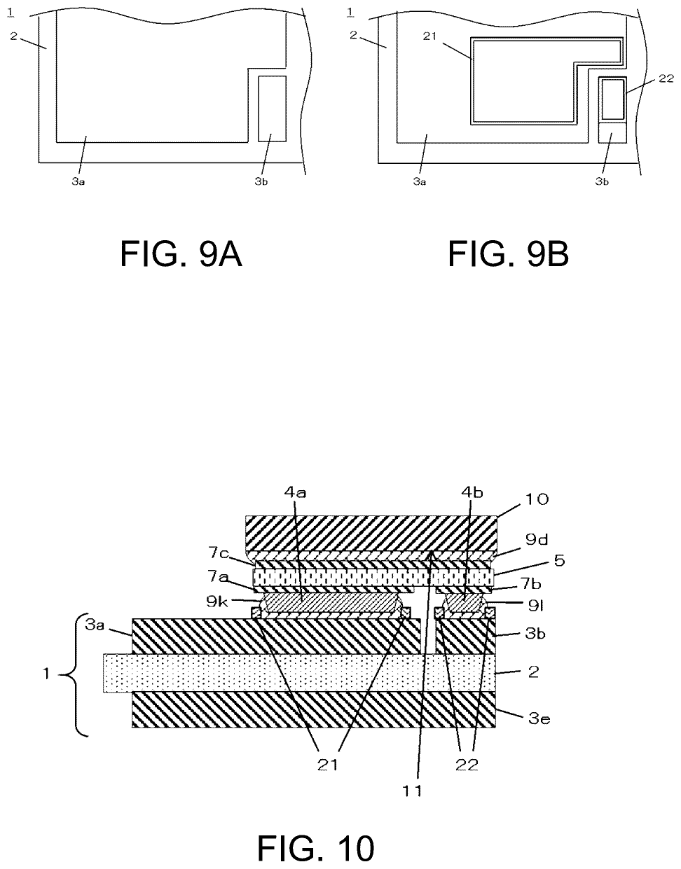

A fourth embodiment of the disclosure will be described with reference to FIG. 9A, FIG. 9B, and FIG. 10. FIG. 9A and FIG. 9B are plan views, and FIG. 10 is a lateral cross-sectional view.

The fourth embodiment differs from the first embodiment in that insulating resists are included. FIG. 9A is an enlarged view of the substrate 1, and is an enlarged view of a lower left portion in FIG. 2A of the first embodiment. Different from the first embodiment, in FIG. 9B, insulating resists 21 and 22 are applied to surround parts of regions on the conductive patterns 3a and 3b, and spacers 4a and 4b are disposed in the regions surrounded by the insulating resists 21 and 22 and are bonded by solders 9k and 9l.

In other words, the insulating resists 21 and 22 are provided around the spacers 4a and 4b on the conductive patterns 3a and 3b of the substrate 1, and the semiconductor element 5 and the conductive patterns 3a and 3b are bonded to each other by the solders 9k and 9l.

With such a configuration, the solders 9k and 9l melted on the conductive patterns 3a and 3b are dammed by the insulating resists 21 and 22 and do not spread further outward. In addition to bonding opposing surfaces of the conductive patterns 3a and 3b and the spacers 4a and 4b, the solders 9k and 9l climb up in gaps between inner sides of the insulating resists 21 and 22 and peripheries of the spacers 4a and 4b and also adhere to lateral surfaces of the spacers 4a and 4b. As a result, the solders 9k and 9l can provide bonding by wrapping from lower surfaces to lateral surfaces of the spacers 4a and 4b. Accordingly, the semiconductor element 5 and the conductive patterns 3a and 3b can be reliably bonded to each other.

Of course, the fourth embodiment may be applied to the second embodiment and the third embodiment.

### Fifth Embodiment

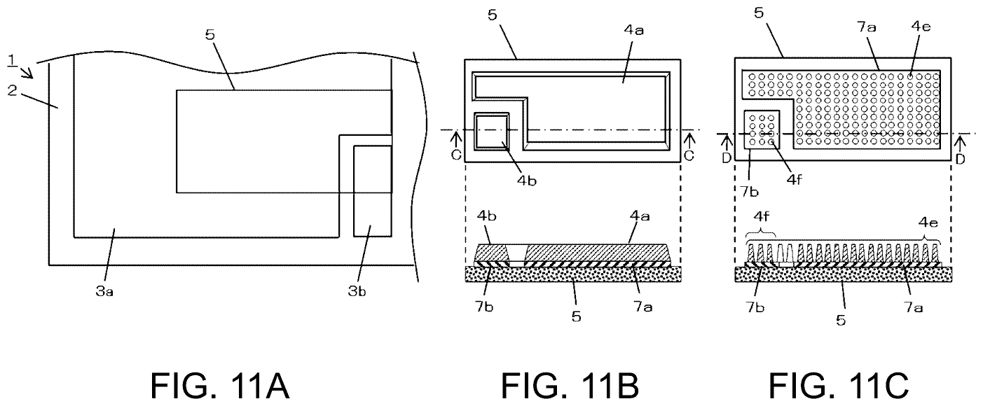

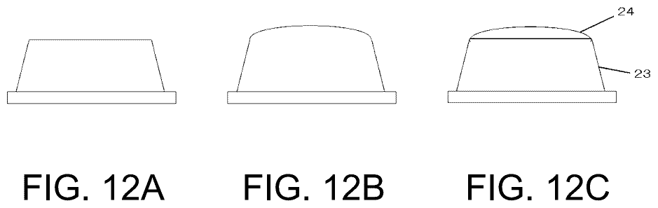

A fifth embodiment of the disclosure will be described with reference to FIG. 11A to FIG. 12C. FIG. 11A, FIG. 11B, and FIG. 11C are schematic views of a semiconductor device and a semiconductor element. FIG. 12A, FIG. 12B, and FIG. 12C are schematic views of exemplary Cu pillars.

The fifth embodiment differs from the first embodiment in that Cu pillars are used as spacers. FIG. 11A is an enlarged view of the substrate 1, and is an enlarged view of a lower left portion in FIG. 2B of the first embodiment. FIG. 11B is a schematic view of the semiconductor element 5 in the first embodiment, with an upper part of the view showing the semiconductor element 5 in FIG. 11A flipped in a left-right direction, and a lower part of the view being a cross-sectional view taken along line C-C in the upper part of the view. Spacers 4a and 4b having bottom shapes substantially identical to the electrodes 7a and 7b are respectively configured on the electrodes 7a and 7b of the semiconductor element 5. In this case, the number of electrodes and the number of spacers are the same as each other (both being two). On the other hand, FIG. 11C is a configuration view of the semiconductor element 5 using Cu pillars of this embodiment, with the lower part of the view being a cross-sectional view taken along line D-D in the upper part of the view. Compared to FIG. 11B, in FIG. 11C, the semiconductor element 5 and the electrodes 7a and 7b have the same configurations, but the spacers 4e and 4f are composed of Cu pillars in a quantity much larger than the electrodes. Specifically, 159 Cu pillars are provided as the spacer 4e on the electrode 7a, and 12 Cu pillars are provided as the spacer 4f on the electrode 7b.

As described above, the spacers 4e and 4f in this embodiment are Cu pillars.

With such Cu pillars, the conductive spacers 4e and 4f which connect the plurality of electrodes 7a and 7b and the conductive patterns 3a and 3b can be reliably realized.

Particularly, in the case of bonding the electrodes 7a and 7b and the conductive patterns 3a and 3b by solders, with the solders entering gaps between the Cu pillars of the spacers 4e and 4f, the bonding can be strengthened.

FIG. 12A, FIG. 12B, and FIG. 12C are views schematically illustrating exemplary shapes of Cu pillars. FIG. 12A shows a trapezoidal shape, FIG. 12B shows a dome shape, and FIG. 12C shows a Cu pillar 23 formed by Cu plating, with a Sn plating 24 for surface protection applied to an upper part of the Cu pillar 23. The Sn plating 24 has effects of preventing oxidation of Cu and improving solderability.

Of course, the fifth embodiment may be applied to the second embodiment, the third embodiment, and the fourth embodiment.

The disclosure includes the following aspects.

[1]:

A semiconductor device including a semiconductor element on a substrate having a conductive pattern, wherein
the semiconductor element includes a plurality of electrodes provided on a first surface and an electrode provided on a second surface, each of the plurality of electrodes provided on the first surface is bonded to the conductive pattern of the substrate via a conductive spacer, and the electrode provided on the second surface is bonded to a pad surface of a conductive clip lead.

[2]:

The semiconductor device according to [1], wherein the clip lead further includes a terminal surface, and the terminal surface is bonded to the conductive pattern of the substrate.

[3]:

The semiconductor device according to [1], wherein a wire for wiring is bonded to a surface of the clip lead opposite to the pad surface.

[4]:

The semiconductor device according to any one of [1] to [3], further including an insulating resist provided around the spacer on the conductive pattern of the substrate, wherein the semiconductor element and the conductive pattern are bonded to each other by a solder.

[5]:

The semiconductor device according to any one of [1] to [4], wherein the spacer is a Cu pillar.

The disclosure is not limited to the above embodiments. The above embodiments are examples, and any configuration that involves substantially the same technical spirit described in the claims of the disclosure and exhibits similar effects is included in the technical scope of the disclosure.

What is claimed is:

1. A semiconductor device comprising a semiconductor element on a substrate having a conductive pattern, wherein
the semiconductor element comprises a plurality of electrodes provided on a first surface and an electrode provided on a second surface, each of the plurality of electrodes provided on the first surface is bonded to the conductive pattern of the substrate via a conductive spacer, and the electrode provided on the second surface is bonded to a pad surface of a conductive clip lead.

2. The semiconductor device according to claim 1, wherein the clip lead further comprises a terminal surface, and the terminal surface is bonded to the conductive pattern of the substrate.

3. The semiconductor device according to claim 1, wherein a wire for wiring is bonded to a surface of the clip lead opposite to the pad surface.

4. The semiconductor device according to claim 1, further comprising an insulating resist provided around the spacer on the conductive pattern of the substrate, wherein the semiconductor element and the conductive pattern are bonded to each other by a solder.

5. The semiconductor device according to claim 1, wherein the spacer is a Cu pillar.
